(19) United States
(12) Patent Application Publication
(10) Pub. No.: US 2026/0144035 A1
(43) Pub. Date: May 21, 2026

(54) SEMICONDUCTOR DEVICE AND SEMICONDUCTOR PACKAGE INCLUDING THE SAME

(71) Applicant: Samsung Electronics Co., Ltd., Suwon-si (KR)

(72) Inventors: Jisoo KIM, Suwon-si (KR); Jinkyu KIM, Suwon-si (KR); Hojun CHOI, Suwon-si (KR); Hyunjun BAE, Suwon-si (KR); KyuTae JEONG, Suwon-si (KR); Dong-Hwan HAN, Suwon-si (KR); Jeongeun HER, Suwon-si (KR)

(73) Assignee: Samsung Electronics Co., Ltd., Suwon-si (KR)

(21) Appl. No.: 19/240,528

(22) Filed: Jun. 17, 2025

(30) Foreign Application Priority Data
Nov. 18, 2024 (KR) 10-2024-0164433

(51) Int. Cl. H01L 23/48; H01L 23/528; H01L 25/18; H10B 80/00; H10D 30/00; H10D 62/10; H10D 80/30; H10D 84/83

(52) U.S. Cl. CPC H10W 20/20; H10W 20/43; H10W 20/435; H10B 80/00; H10D 30/506; H10D 62/121; H10D 80/30; H10D 84/832; H10W 72/823; H10W 90/00; H10W 90/722

(57) ABSTRACT

Disclosed are semiconductor devices and semiconductor packages. Some example embodiments of a semiconductor device comprises a first substrate having a first surface and a second surface facing each other, a logic block on the first surface, a power delivery network on the second surface including a plurality of backside lines connected to the logic block, a second substrate on the logic block opposite to the first surface of the first substrate, a first through structure penetrating the first substrate, and a second through structure penetrating the second substrate and electrically connected to the first through structure. The first through structure comprises a through conductive pattern horizontally spaced apart from the logic block and penetrating the first substrate, a plurality of upper conductive patterns stacked on a top surface of the through conductive pattern, and a plurality of lower conductive patterns stacked on a bottom surface of the through conductive pattern.

### CROSS-REFERENCE TO RELATED APPLICATION

This application claims priority under 35 U.S.C. § 119 to Korean Patent Application No. 10-2024-0164433 filed on Nov. 18, 2024 in the Korean Intellectual Property Office, the disclosure of which is hereby incorporated by reference in its entirety.

### BACKGROUND

Example embodiments of the present inventive concepts relate to a semiconductor device and a semiconductor package including the same.

Semiconductor devices may include integrated circuits consisting of metal oxide semiconductor field effect transistors (MOSFETs). As sizes and design rules of semiconductor devices gradually decrease, sizes of MOSFETs may also be increasingly scaled down. The scale down of MOSFETs may deteriorate the operating characteristics of semiconductor devices. Accordingly, research has been ongoing to manufacture semiconductor devices having excellent performance while overcoming limitations which may be caused by the higher integration designs of the semiconductor devices.

Additionally, as 3-dimensional semiconductor packages including a plurality of semiconductor chips mounted in a single semiconductor package are being actively developed, there may be a need for securing the electrical and/or mechanical stability of the connection structures that vertically penetrate a substrate or a die to form electrical couplings.

### SUMMARY

Some example embodiments of the present inventive concepts provide a semiconductor device including an electrical path structure electrically connecting top and bottom ends of the semiconductor device. The semiconductor device may be included in a semiconductor package and may exhibit improved space optimization and/or improved thermal radiation performance.

The example embodiments of the present inventive concepts are not limited to the disclosure mentioned above, and other objects which have not been mentioned above will be clearly understood to those skilled in the art from the following description.

According to some example embodiments of the present inventive concepts, a semiconductor device may comprise a first substrate having a first surface and a second surface facing each other, a logic block on the first surface of the first substrate, a power delivery network on the second surface of the first substrate, and the power delivery network including a plurality of backside lines connected to the logic block, a second substrate on the logic block opposite to the first surface of the first substrate, a first through structure penetrating the first substrate, and a second through structure penetrating the second substrate, and the second through structure electrically connected to the first through structure. The first through structure comprises a through conductive pattern horizontally spaced apart from the logic block and penetrating the first substrate, a plurality of upper conductive patterns stacked on a top surface of the through conductive pattern, and a plurality of lower conductive patterns stacked on a bottom surface of the through conductive pattern.

According to some example embodiments of the present inventive concepts, a semiconductor device may comprise a first substrate having a first surface and a second surface facing each other, a logic block on the first surface of the first substrate, a plurality of upper lines on the first surface of the first substrate and connected to the logic block, a power delivery network on the second surface of the first substrate, and the power delivery network including a plurality of backside lines connected to the logic block, a second substrate on the logic block opposite to the first surface of the first substrate, and a connection structure penetrating the first substrate and the second substrate. The connection structure comprises a through conductive pattern penetrating the first substrate, and the through conductive pattern is horizontally spaced apart from the logic block, and an upper through structure penetrating the second substrate, and the upper through structure electrically connected to the through conductive pattern. A bottom surface of the upper through structure is at a level lower than a level of a top surface of an uppermost one of the upper lines.

According to some example embodiments of the present inventive concepts, a semiconductor package may comprise a redistribution substrate, a first semiconductor chip on the redistribution substrate, and a second semiconductor chip on the first semiconductor chip. The first semiconductor chip comprises a logic block on a first surface of a first substrate, an upper line on the first surface of the first substrate, and the upper line connected to the logic block, a power delivery network on a second surface of the first substrate, and the power delivery network including a plurality of power lines connected to the logic block, a second substrate on the logic block opposite to the first surface of the first substrate, and a connection structure penetrating the first substrate and the second substrate. The connection structure comprises a first through structure penetrating the first substrate, and a second through structure penetrating the second substrate, and the second through structure electrically connected to the first through structure. The first through structure comprises a through conductive pattern penetrating the first substrate, and the through conductive pattern is horizontally spaced apart from the logic block, a plurality of upper conductive patterns on the first surface of the first substrate, and the plurality of upper conductive patterns stacked on a top surface of the through conductive pattern, and a plurality of lower conductive patterns on the second surface of the first substrate, and the plurality of lower conductive patterns stacked on a bottom surface of the through conductive pattern.

According to some example embodiments of the present inventive concepts, a method of manufacturing a semiconductor device may comprise forming a first active pattern on a first surface of a first substrate, forming a second active pattern on the first surface of the first substrate, forming a device isolation layer between the first and second active patterns, forming a gate electrode and active contacts on the first active pattern and the second active pattern, forming a first interlayer dielectric layer surrounding the first active pattern and the second active pattern, forming a second interlayer dielectric layer on the first interlayer dielectric layer, forming upper lines in a third interlayer dielectric layer on the second interlayer dielectric layer, forming upper conductive patterns and upper conductive vias in the third interlayer dielectric layer, forming a trench on a second substrate including a sacrificial pattern filling the trench, adhering the second substrate to the third interlayer dielectric layer of the first substrate, performing a thinning process on a second surface of the first substrate, forming a replacement dielectric substrate on the second surface of the first substrate, forming through holes exposing one or more active contacts in the replacement dielectric substrate, forming backside contacts in the through holes, forming a through conductive pattern penetrating the replacement dielectric substrate, forming a power delivery network on the replacement dielectric substrate contacting the backside contacts, and forming a lower conductive patterns and lower conductive vias on the through conductive pattern.

According to some example embodiments of the present inventive concepts, a thermal conductivity of the second substrate is greater than a thermal conductivity of the third interlayer dielectric layer.

### BRIEF DESCRIPTION OF DRAWINGS

FIG. 1 illustrates a cross-sectional view showing a semiconductor package including a semiconductor device according to some example embodiments of the present inventive concepts.

FIG. 2 illustrates a simplified plan view showing a semiconductor device according to some example embodiments of the present inventive concepts.

FIG. 3 illustrates a cross-sectional view showing section P1 of FIG. 2.

FIG. 4 illustrates a cross-sectional view taken along line A-A′ of FIG. 3, partially showing a semiconductor device according to some example embodiments of the present inventive concepts.

FIGS. 5A to 5D illustrate cross-sectional views corresponding to FIG. 4 and partially showing a semiconductor device according to some example embodiments of the present inventive concepts.

FIG. 6 illustrates a simplified plan view showing a logic block provided on a semiconductor device according to some example embodiments of the present inventive concepts.

FIG. 7 illustrates a plan view partially showing a semiconductor device according to some example embodiments of the present inventive concepts.

FIG. 8 illustrates a cross-sectional view taken along line I-I′ of FIG. 7, showing a semiconductor device according to some example embodiments of the present inventive concepts.

FIG. 9 illustrates a cross-sectional view showing a semiconductor package including a semiconductor device according to some example embodiments of the present inventive concepts.

FIGS. 10 to 12E illustrate cross-sectional views showing a method of fabricating a semiconductor device according to some example embodiments of the present inventive concepts.

FIGS. 13A to 13D illustrate cross-sectional views showing a method of fabricating a semiconductor device according to some example embodiments of the present inventive concepts.

### DETAILED DESCRIPTION OF EMBODIMENTS

Hereinafter, a semiconductor device, and a semiconductor package including the same, according to some example embodiments of the present inventive concepts will be discussed in conjunction with the accompanying drawings.

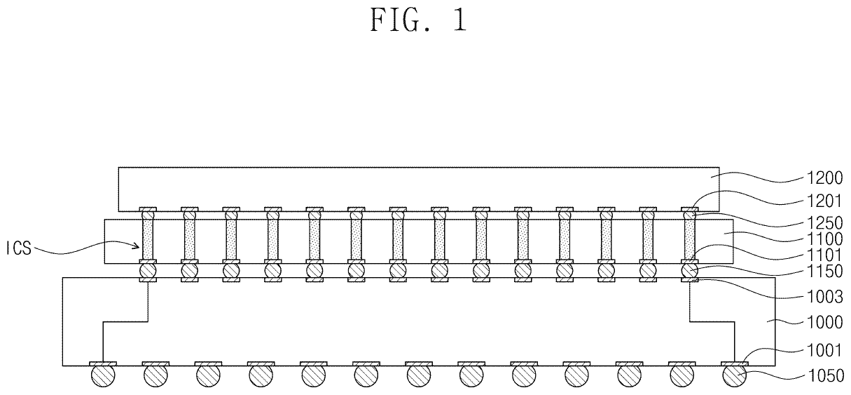

FIG. 1 illustrates a cross-sectional view showing a semiconductor package including a semiconductor device according to some example embodiments of the present inventive concepts.

Referring to FIG. 1, a semiconductor package may include a first redistribution substrate 1000, a first semiconductor device 1100, and a second semiconductor device 1200.

The first redistribution substrate 1000 may include lower bonding pads 1001 disposed on a bottom surface thereof and upper bonding pads 1003 disposed on a top surface thereof. The first redistribution substrate 1000 may include a plurality of base dielectric layers and a plurality of redistribution patterns. The redistribution patterns may include conductive line patterns that reside on the base dielectric layers and conductive vias that vertically penetrate the base dielectric layers.

First connection terminals 1050 may be attached to the lower bonding pads 1001 of the first redistribution substrate 1000. The first connection terminals 1050 may be at least one selected from solder balls, conductive bumps, and conductive pillars. The first connection terminals 1050 may include at least one selected from copper, tin, and lead. However, example embodiments are not limited thereto.

The semiconductor package may use the first connection terminals 1050 to transceive signals with an external other package or other semiconductor devices. For example, a power signal (or a ground signal) for driving the first and second semiconductor devices 1100 and 1200 may be received through at least one among the first connection terminals 1050 of the first redistribution substrate 1000.

The first semiconductor device 1100 may be mounted on the first redistribution substrate 1000. The first semiconductor device 1100 may be a logic chip including a processor, such as a microelectromechanical system (MEMS) device, an optoelectronic device, a central processing unit (CPU), a graphic processing unit (GPU), a mobile application, or a digital signal processor (DSP). However, example embodiments are not limited thereto.

The first semiconductor device 1100 may include connection structures ICS that connect top and bottom surfaces thereof. A power signal may be provided from the first redistribution substrate 1000 through at least one of the connection structures ICS to the second semiconductor device 1200. The first semiconductor device 1100 may include lower chip pads 1101 disposed on a bottom surface thereof.

Second connection terminals 1150 may be provided between the upper bonding pads 1003 of the first redistribution substrate 1000 and the lower chip pads 1101 of the first semiconductor device 1100. The second connection terminals 1150 may be solder balls or bumps formed of tin, lead, or copper. For example, the second connection terminals 1150 may be smaller than the first connection terminals 1050.

The second semiconductor device 1200 may be mounted on the first semiconductor device 1100. The second semiconductor device 1200 may receive power and signals through the first semiconductor device 1100 from the first redistribution substrate 1000.

The second semiconductor device 1200 may be supplied with a power voltage from the first redistribution substrate 1000 through one or more of the connection structures ICS in the first semiconductor device 1100, and may be supplied with a ground voltage from the first redistribution substrate 1000 through another or more of the connection structures ICS. In addition, the second semiconductor device 1200 may transceive signals with the first semiconductor device 1100 through still another or more of the connection structures ICS in the first semiconductor device 1100.

The second semiconductor device 1200 may be a single chip or a chip stack in which a plurality of chips are stacked. The second semiconductor device 1200 may include a memory cell array, a column decoder, a row decoder, a sense amplifier, a write driver, and an input/output buffer. However, example embodiments are not limited thereto.

The first semiconductor device 1100 and the second semiconductor device 1200 may be connected to each other through third connection terminals 1250. The third connection terminals 1250 may electrically connect the connection structures ICS of the first semiconductor device 1100 to lower chip pads 1201 of the second semiconductor device 1200. The third connection terminals 1250 may be solder balls or bumps formed of tin, lead, or copper. For example, the third connection terminals 1250 may be smaller than the second connection terminals 1150.

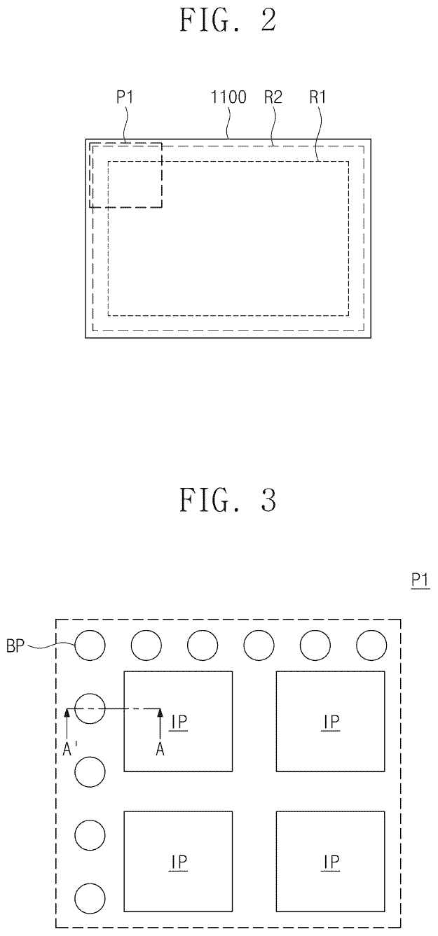

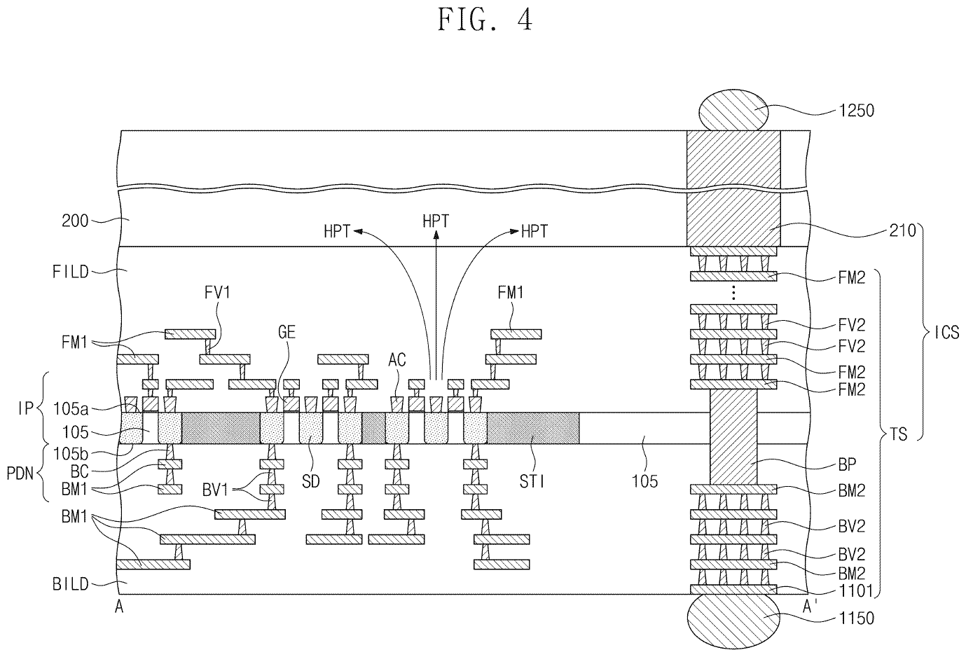

FIG. 2 illustrates a simplified plan view showing a semiconductor device according to some example embodiments of the present inventive concepts. FIG. 3 illustrates a cross-sectional view showing section P1 of FIG. 2. FIG. 4 illustrates a cross-sectional view taken along line A-A′ of FIG. 3, partially showing a semiconductor device according to some example embodiments of the present inventive concepts.

Referring to FIGS. 2 and 3, the first semiconductor device 1100 may include a central region R1 and an edge region R2 around the central region R1. Logic blocks IP may be disposed on the central region R1 of the first semiconductor device 1100. The connection structures ICS may be disposed on the edge region R2 of the first semiconductor device 1100.

The logic blocks IP may be arranged in a matrix form. The logic blocks IP may be called functional blocks, hard macros, or intellectual properties (IP). The logic blocks IP may refer to blocks that are reusable and achieved to have interconnection and fixed layout that are specified to perform desirable electric functions. For example, the logic blocks IP may include macro blocks for data processing and/or calculation and memory blocks for data storage. The logic blocks IP may include a plurality of standard cells or logic cells. The standard cells may mean a logic device, such as AND, OR, XOR, XNOR, and inverter, that performs a specific function. However, example embodiments are not limited thereto. For example, the standard cells may include transistors for constituting a logic device and wiring lines for connecting the transistors to each other.

Referring to FIGS. 3 and 4, the first semiconductor device 1100 may include a first substrate 105, logic blocks IP, a power delivery network (or power distribution network) PDN, a second substrate 200, and connection structures ICS that vertically penetrate the first semiconductor device 1100.

The first substrate 105 may have a first surface 105a and a second surface 105b that face each other. The first substrate 105 may include a silicon-based dielectric layer. The first substrate 105 may be a semiconductor substrate or a dielectric substrate. For example, the first substrate 105 may include a silicon substrate, and for another example, the first substrate 105 may include a silicon oxide layer, a silicon nitride layer, or a silicon oxynitride layer. However, example embodiments are not limited thereto.

The first substrate 105 may be provided therein with a device isolation layer STI that defines active regions. The device isolation layer STI may be formed of a dielectric material, such as silicon oxide.

The logic blocks IP may be integrated on the first surface 105a of the first substrate 105. The logic blocks IP may be AND, OR, NOR, inverter, or latch. In addition, the logic blocks IP may include field effect transistors and resistors.

According to some example embodiments, the logic blocks IP may include gate electrodes GE disposed on the first surface 105a of the first substrate 105 and source/drain patterns SD in the first substrate 105 on opposite sides of each of the gate electrodes GE. Active contacts AC may be electrically connected to the source/drain patterns SD.

On the first surface 105a of the first substrate 105, upper lines FM1 may be connected to the logic blocks IP. The upper lines FM1 may be electrically connected through contact plugs to the gate electrodes GE and the active contacts AC. The upper lines FM1 may include a plurality of metal lines that are stacked across a front interlayer dielectric layer FILD, and the upper lines FM1 of other layers may be electrically connected through upper vias FV1. The upper lines FM1 may include clock line that transfer clock signals and signal lines that transfer ordinary signals.

The front interlayer dielectric layer FILD may be disposed on the first surface 105a of the first substrate 105. On the first surface 105a, the front interlayer dielectric layer FILD may cover the logic blocks IP, the upper lines FM1, and the upper vias FV1. The front interlayer dielectric layer FILD may include a multi-layered dielectric layer including, for example, at least one selected from silicon oxide, silicon nitride, and silicon oxynitride. However, example embodiments are not limited thereto.

The second substrate 200 may be disposed on the first surface 105a of the first substrate 105. The second substrate 200 may be disposed on the logic blocks IP and the front interlayer dielectric layer FILD, and a bottom surface of the second substrate 200 may face the first surface 105a of the first substrate 105. For example, an adhesion layer (not shown) may be additionally disposed between the second substrate 200 and the front interlayer dielectric layer FILD. The second substrate 200 may be a semiconductor substrate, such as a silicon substrate, and may further include silicon carbide. However, example embodiments are not limited thereto. The second substrate 200 may exhibit thermal conductivity relatively superior to that of the front interlayer dielectric layer FILD.

The power delivery network PDN may be provided on the second surface 105b of the first substrate 105. The power delivery network PDN may include a plurality of backside lines BM1 across a backside interlayer dielectric layer BILD therebetween. Some of the backside lines BM1 may be power lines that transfer power voltage or ground voltage. The backside interlayer dielectric layer BILD may include a plurality of dielectric layers including, for example, at least one selected from silicon oxide, silicon nitride, and silicon oxynitride.

Power lines of the backside lines BM1 may be electrically connected to the source/drain patterns SD through backside contacts BC that penetrate the first substrate 105. The backside contacts BC may have a diameter of, for example, about several nanometers to several micrometers. The backside contacts BC may have a vertical length of, for example, about several tens of nanometers to several micrometers. Although not shown, a dielectric layer (not shown) may be interposed between the first substrate 105 and sidewalls of the backside contacts BC. The backside lines BM1 and the backside contacts BC may include a metallic material, such as W, WN, WC, Ti, TiN, Ta, TaN, Ru, Co, Mn, WN, Ni, or NiB. However, example embodiments are not limited thereto.

According to some example embodiments, the connection structures ICS may vertically penetrate the first substrate 105 and the second substrate 200. Each of the connection structures ICS may include a first through structure TS that vertically penetrates the first substrate 105 and a second through structure 210 that vertically penetrates the second substrate 200. The connection structures ICS may be disposed horizontally spaced apart from the logic blocks IP. The connection structures ICS may connect the first redistribution substrate (see 1000 of FIG. 1) to the second semiconductor device (see 1200 of FIG. 1). The connection structures ICS may transfer power or ground voltage from the first redistribution substrate 1000 to the second semiconductor device 1200.

The first through structure TS may vertically extend, while penetrating the first substrate 105. The first through structure TS may include a through conductive pattern BP, upper conductive patterns FM2, and lower conductive patterns BM2 that penetrates the first substrate 105. The through conductive pattern BP, the upper conductive patterns FM2, and the lower conductive patterns BM2 may vertically overlap each other. A lowermost one of the lower conductive patterns BM2 may be called the lower chip pad 1101. The second connection terminal 1150 may be attached to a bottom surface of the lower chip pad 1101.

The upper conductive patterns FM2 may be vertically stacked on a top surface of the through conductive pattern BP. For example, the upper conductive patterns FM2 may vertically overlap the through conductive pattern BP. The upper conductive patterns FM2 may be disposed on the first surface 105a of the first substrate 105. The upper conductive patterns FM2 may have a square shape, a rectangular shape, or a polygonal shape when viewed in plan. The shape of the upper conductive patterns FM2 is not limited thereto, and may be variously changed in consideration of resistance of each pattern. For example, a lowermost one of the upper conductive patterns FM2 may cover the top surface of the through conductive pattern BP. The stack number and stack level of the upper conductive patterns FM2 may be variously changed.

Some of the upper conductive patterns FM2 may be located at substantially the same level as that of the upper lines FM1 connected to the logic blocks IP. For example, a top surface of the lowermost one of the upper conductive patterns FM2 may be substantially coplanar with that of at least one of the upper lines FM1. Some of the lower conductive patterns BM2 may be located at substantially the same level as that of the backside lines BM1 connected to the logic blocks IP. For example, a bottom surface of an uppermost one of the lower conductive patterns BM2 may be substantially coplanar with that of at least one of the backside lines BM1.

The lower conductive patterns BM2 may be vertically stacked on a bottom surface of the through conductive pattern BP. For example, the lower conductive patterns BM2 may vertically overlap the through conductive pattern BP. The lower conductive patterns BM2 may be disposed on the second surface 105b of the first substrate 105. The lower conductive patterns BM2 may have a square shape, a rectangular shape, or a polygonal shape when viewed in plan. The shape of the lower conductive patterns BM2 is not limited thereto, and may be variously changed in consideration of resistance of each pattern. For example, the uppermost one of the lower conductive patterns BM2 may cover the bottom surface of the through conductive pattern BP. The stack number and stack level of the lower conductive patterns BM2 may be variously changed.

The first through structure TS may further include upper conductive vias FV2 disposed between the upper conductive patterns FM2 and lower conductive vias BV2 disposed between the lower conductive patterns BM2. The upper conductive vias FV2 may be disposed between the upper conductive patterns FM2 that are vertically adjacent to each other, and may electrically connect neighboring upper conductive patterns FM2 to each other. The lower conductive vias BV2 may be disposed between the lower conductive patterns BM2 that are vertically adjacent to each other, and may electrically connect neighboring lower conductive patterns BM2 to each other.

The through conductive pattern BP may have a vertical length and a diameter less than those of the second through structure 210 which will be discussed below. The through conductive pattern BP may have a diameter (or horizontal width) of, for example, about several tens of nanometers to several tens of micrometers. The top surface of the through conductive pattern BP may be higher than the first surface 105a of the first substrate 105. The through conductive pattern BP may include a metallic material, such as W, WN, WC, Ti, TiN, Ta, TaN, Ru, Co, Mn, WN, Ni, or NiB. However, example embodiments are not limited thereto.

The second through structure 210 may penetrate the second substrate 200. The second through structure 210 may be disposed on the first through structure TS, and may be called an upper through structure. The second through structure 210 may vertically overlap the first through structure TS. The third connection terminal 1250 may be attached to the second through structure 210. A maximum width of each of the third connection terminals 1250 may be less than that of each of the second connection terminals 1150. The maximum widths of the second and third connection terminals 1150 and 1250 may each indicate a width in a horizontal direction. Although not shown, a chip pad may be additionally disposed between the second through structure 210 and the third connection terminal 1250.

On the first through structure TS, the second through structure 210 may be electrically connected to the first structure TS. The second through structure 210 may vertically penetrate the second substrate 200. The second through structure 210 may have a diameter (or horizontal width) of, for example, about several tens of nanometers to about several hundreds of micrometers. For example, the second through structure 210 may have one of a circular shape and an oval shape when viewed in plan, but the present inventive concepts are not limited thereto. When viewed in plan, the second through structure 210 may have a bar shape that extends in one direction. The second through structure 210 may include a metallic material, such as at least one selected from W, WN, WC, Ti, TiN, Ta, TaN, Ru, Co, Mn, WN, Ni, and NiB. However, example embodiments are not limited thereto.

The second through structure 210 may be in contact with the first through structure TS. For example, the second through structure 210 may be in contact with an uppermost one of the upper conductive patterns FM2 of the first through structure TS. The first through structure TS may be connected to the upper conductive patterns FM2 and the upper conductive vias FV2 to come into electrical connection with the through conductive pattern BP. In addition, the second through structure 210 may be electrically connected to the lower conductive patterns BM2 on the bottom surface of the through conductive pattern BP. The second through structure 210 and the first through structure TS may serve as electrical paths that electrically connect top and bottom ends of the first semiconductor chip (see 1100 of FIG. 1) and electrically connect the first redistribution substrate 1000 and the second semiconductor device 1200 discussed with reference to FIG. 1.

For example, when a through structure is provided to integrally penetrate the first and second substrates 105 and 200, the front interlayer dielectric layer FILD, and the backside interlayer dielectric layer BILD, process difficulty may increase because it may be necessary that a recess be formed deep to form the through structure. In addition, since the recess is formed to have an aspect ratio equal to (or substantially equal to) or greater than an aspect ratio of a certain level or greater due to the characteristics of the recess formation, the through structure may be formed to have a large horizontal width. Thus, it may be required to provide a minimum clearance between the through structure and the logic block IP to reduce (and/or minimize) electrical interference between the through structure and the logic block IP, and there may thus be a reduction in space availability (or integration) of a semiconductor chip.

In contrast, according to some example embodiments of the present inventive concepts, as the first and second through structures TS and 210 are individually formed and provided, there may be a reduction in difficulty of etching processes for forming the first and second through structures TS and 210. In addition, since the first through structure TS has a horizontal width relatively less than that of the through structure explained in the aforementioned example, it may be possible to improve space availability (integration) of a semiconductor chip.

In addition, according to some example embodiments of the present inventive concepts, heat generated in accordance with operation of a semiconductor chip may be transferred to the second substrate 200 which may have greater thermal conductivity than the semiconductor chip, and the heat may be outwardly discharged through sidewalls of the second substrate 200. In this sense, a semiconductor chip may improve in thermal radiation performance and may be at least partially reduced and/or prevented from degradation of performance.

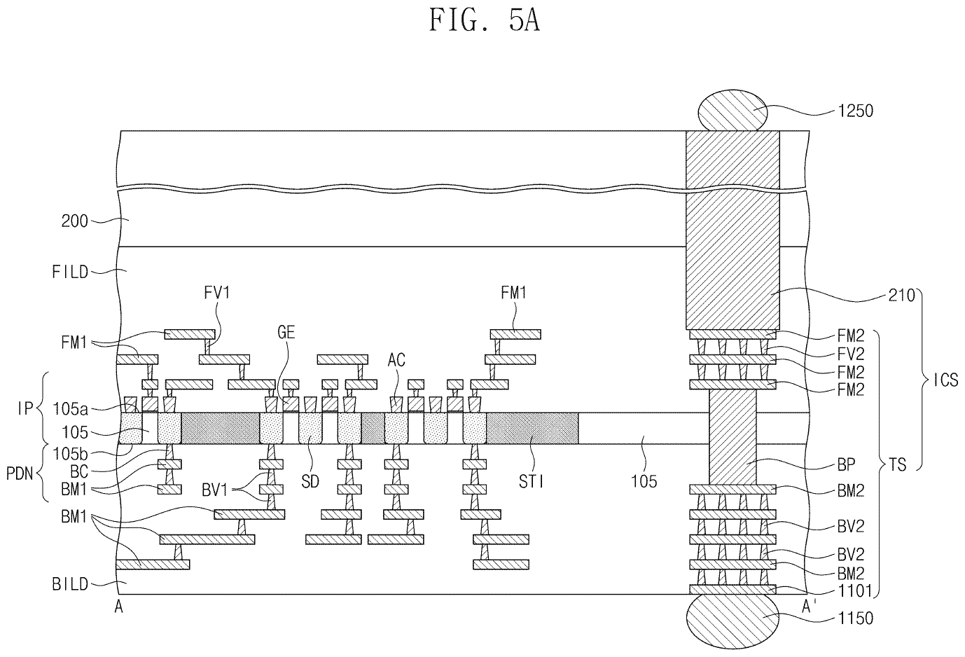

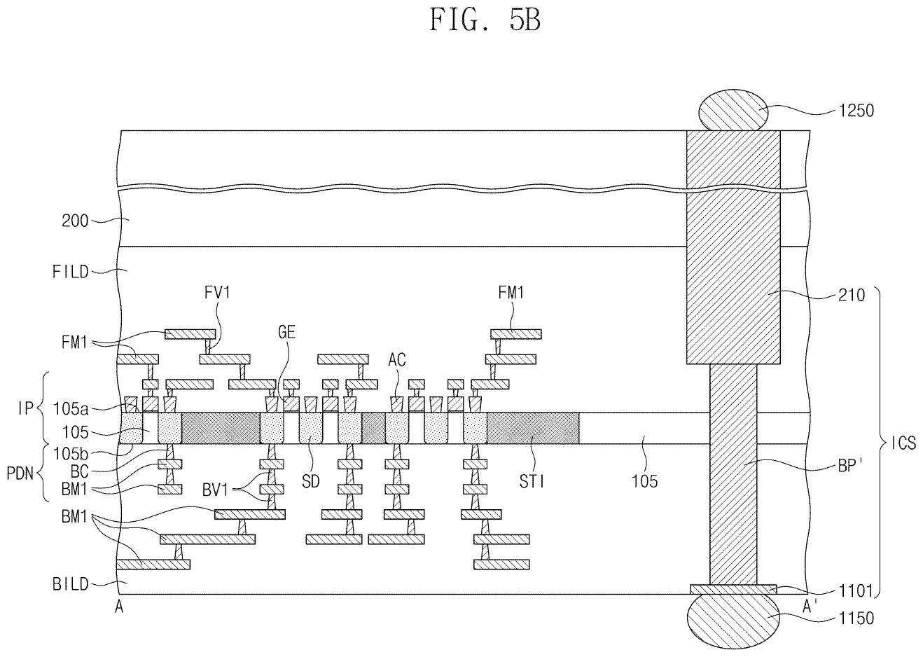

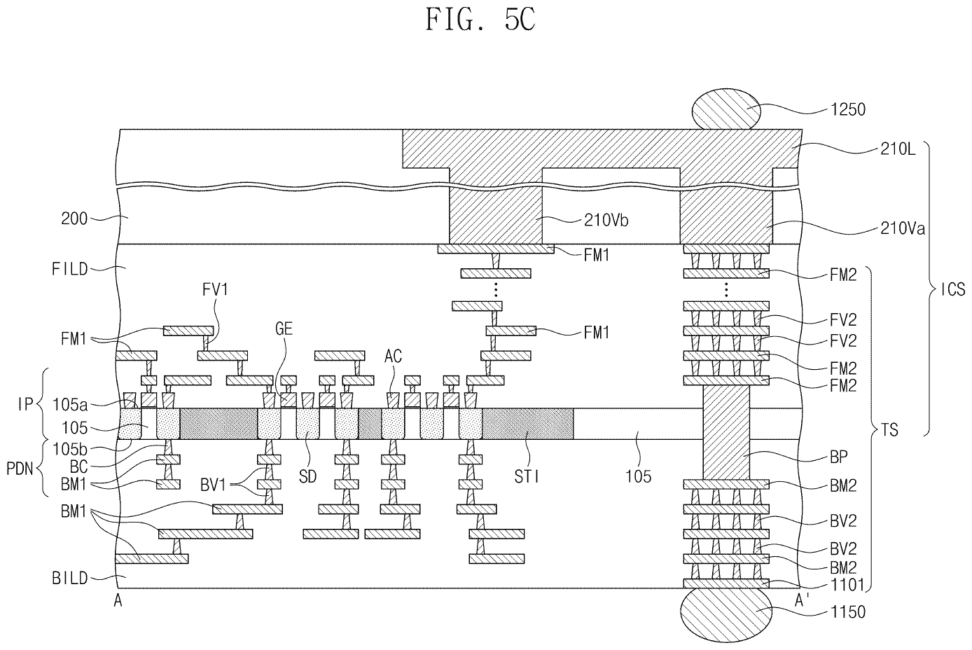

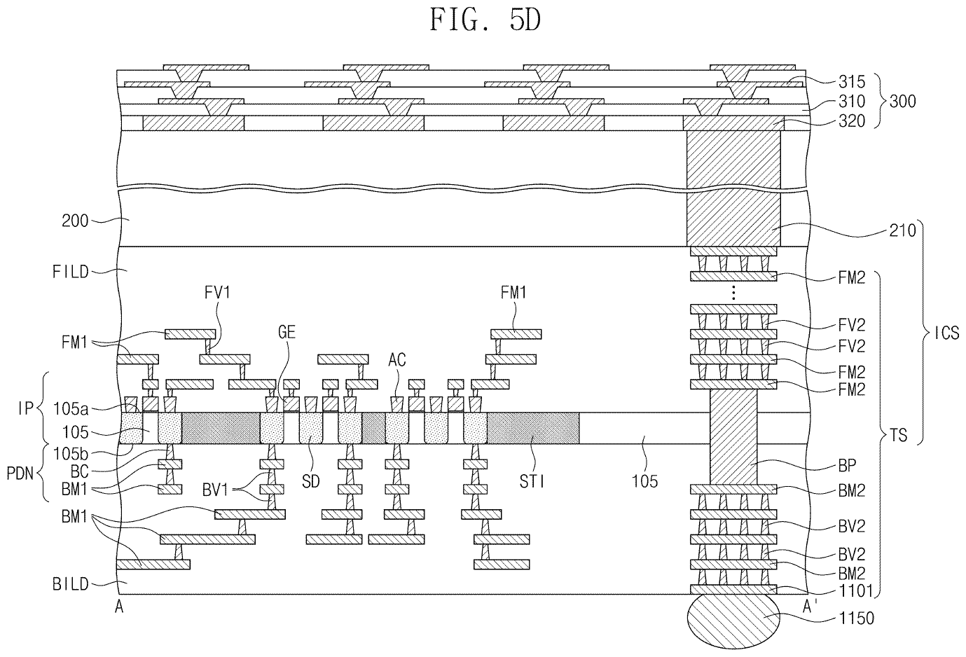

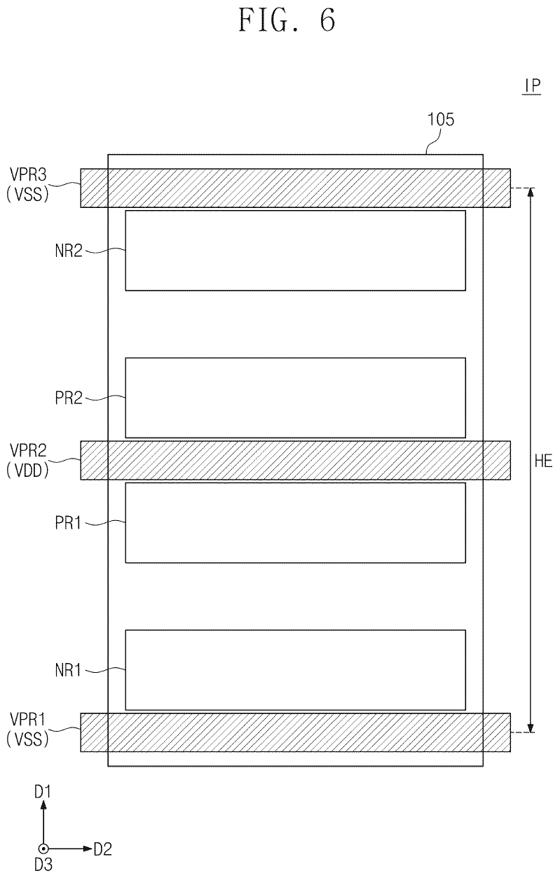

FIGS. 5A to 5D illustrate cross-sectional views corresponding to FIG. 4 and partially showing a semiconductor device according to some example embodiments of the present inventive concepts. For brevity of explanation, a detailed description of technical features the same as those of the semiconductor device discussed above may be omitted, and a difference thereof will be described.

Referring to FIG. 5A, the second through structure 210 may vertically extend to partially penetrate the front interlayer dielectric layer FILD. For example, the second through structure 210 may penetrate the second substrate 200, and may further penetrate a portion of the front interlayer dielectric layer FILD. A vertical length of the second through structure 210 may be greater than that of the second substrate 200. The second through structure 210 may penetrate a portion of the front interlayer dielectric layer FILD and have an electrical connection with the first through structure TS.

The uppermost one of the upper conductive patterns FM2 of the first through structure TS may be located at a lower level than that of a top surface of the front interlayer dielectric layer FILD. The uppermost one of the upper conductive patterns FM2 may be directly connected to the second through structure 210.

Referring to FIG. 5B, a through conductive pattern BP′ may be provided to have a direct connection with the second through structure 210. The through conductive pattern BP′ may vertically extend while penetrating the first substrate 105 and have a direct connection with the second through structure 210. A bottom surface of the through conductive pattern BP′ may be located at a level substantially lower than that of at least one of the backside lines BM1.

The through conductive pattern BP′ may have a vertical length and a diameter greater than those of the backside contacts BC. In addition, the through conductive pattern BP′ may have a vertical length and a diameter less than those of the second through structure 210. The through conductive pattern BP′ may have a diameter (or horizontal width) of, for example, about several tens of nanometers to several tens of micrometers. A bottom surface of the through conductive pattern BP′ may be lower than those of the backside contacts BC, and a top surface of the through conductive pattern BP may be higher than the first surface 105a of the first substrate 105.

The lower chip pad 1101 may be disposed on a bottom end of the through conductive pattern BP′. The through conductive pattern BP′ may be electrically connected to the lower chip pad 1101.

The second through structure 210 may penetrate the second substrate 200 and a portion of the front interlayer dielectric layer FILD. A bottom surface of the second through structure 210 may be located at a lower level than that of a top surface of the front interlayer dielectric layer FILD. In addition, the bottom surface of the second through structure 210 may be located at a lower level than that of top surfaces of some of the upper lines FM1. For example, the bottom surface of the second through structure 210 may be located at a lower level than that of a top surface of an uppermost one of the upper lines FM1.

The bottom surface of the second through structure 210 may be located at a higher level than that of the first surface 105a of the first substrate 105. For example, the second through structure 210 may be vertically spaced apart from the first substrate 105.

The second through structure 210, the through conductive pattern BP′, and the lower chip pad 1101 may be electrically connected to each other, and may serve as an electrical path that connects top and bottom ends of a semiconductor chip.

Referring to FIG. 5C, a second through structure 210L, 210Va, and 210Vb may be provided to have an electrical connection with the first through structure TS. The second through structure 210L, 210Va, and 210Vb may include a first conductive via 210Va that is connected to the first through structure TS, and may also include a conductive line 210L that is connected to the first conductive via 210Va and extends in a direction parallel to a bottom surface of the second substrate 200. The first conductive via 210Va may vertically overlap the first through structure TS. For example, the first conductive via 210Va may have a circular shape or an oval shape when viewed in plan. For example, the conductive line 210L may have a bar shape that extends in one direction when viewed in plan. A top surface of the conductive line 210L may be coplanar (and/or substantially coplanar) with that of the second substrate 200.

The second through structure 210L, 210Va, and 210Vb may further include a second conductive via 210Vb connected to the conductive line 210L. The second conductive via 210Vb may be horizontally spaced apart from the first conductive via 210Va. For example, the second conductive via 210Vb may be electrically connected to the upper lines FM1 connected to the logic blocks IP. The logic blocks IP may be electrically connected to the second semiconductor chip (see 1200 of FIG. 1) through the upper lines FM1, the second conductive via 210Vb, and the conductive line 210L.

Referring to FIG. 5D, a second redistribution substrate 300 may be disposed on the second through structure 210. The second redistribution substrate 300 may include a plurality of base dielectric layers 310 and a plurality of redistribution patterns 315 and 320. The redistribution patterns 315 and 320 may include redistribution pads 320 in a lowermost base dielectric layer 310. Although not shown, the third connection terminals (see 1250 of FIG. 4) may be disposed on the second redistribution substrate 300.

The second through structure 210 may be electrically connected to the redistribution patterns 315 and 320 of the second redistribution substrate 300. The connection structure ICS may receive power and signals from the first redistribution substrate 1000 discussed in FIG. 1, and may transfer the power and the signals to the second redistribution substrate 300 and the second semiconductor device 1200.

FIG. 6 illustrates a simplified plan view showing a logic block provided on a portion of a semiconductor device according to some example embodiments of the present inventive concepts.

Referring to FIG. 6, the first substrate 105 may be provided thereon with a first lower power line VPR1, a second lower power line VPR2, and a third lower power line VPR3. The second lower power line VPR2 may be disposed between the first lower power line VPR1 and the third lower power line VPR3.

The first substrate 105 of the logic block IP may include a first PMOSFET region PR1, a second PMOSFET region PR2, a first NMOSFET region NR1, and a second NMOSFET region NR2.

The first NMOSFET region NR1 may be adjacent to the first lower power line VPR1. The second NMOSFET region NR2 may be adjacent to the third lower power line VPR3. The first and second PMOSFET regions PR1 and PR2 may be adjacent to the second lower power line VPR2. When viewed in plan, the second lower power line VPR2 may be disposed between the first and second PMOSFET regions PR1 and PR2.

A first height HE may be defined to refer to a length in a first direction D1 of the logic block IP. The first height HE may be about twice a distance (e.g., pitch) between the first lower power line VPR1 and the second lower power line VPR2. The first and second PMOSFET regions PR1 and PR2 of the logic block IP may collectively operate as a single PMOSFET region.

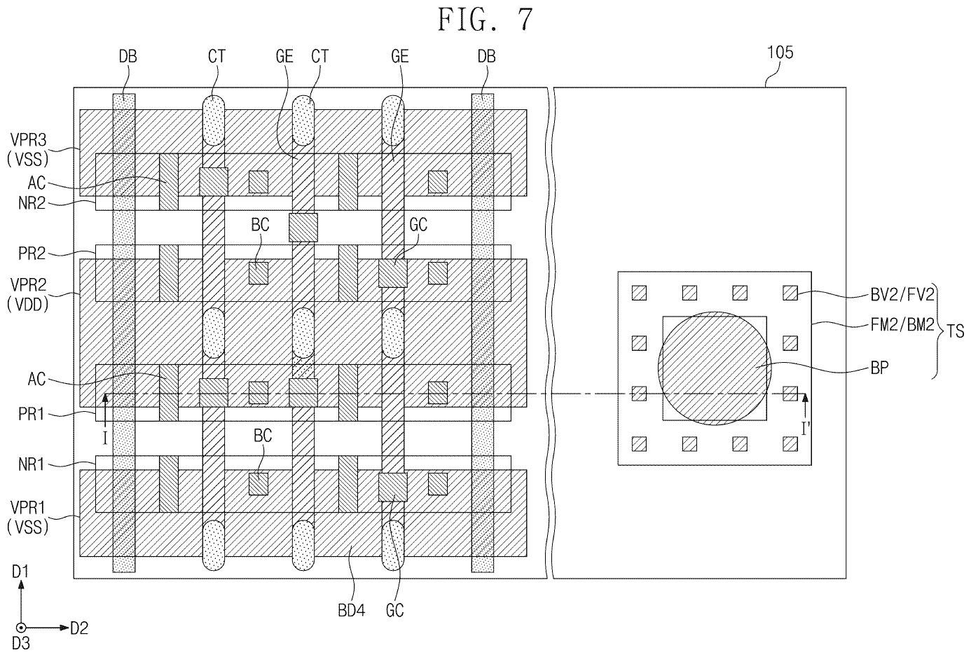

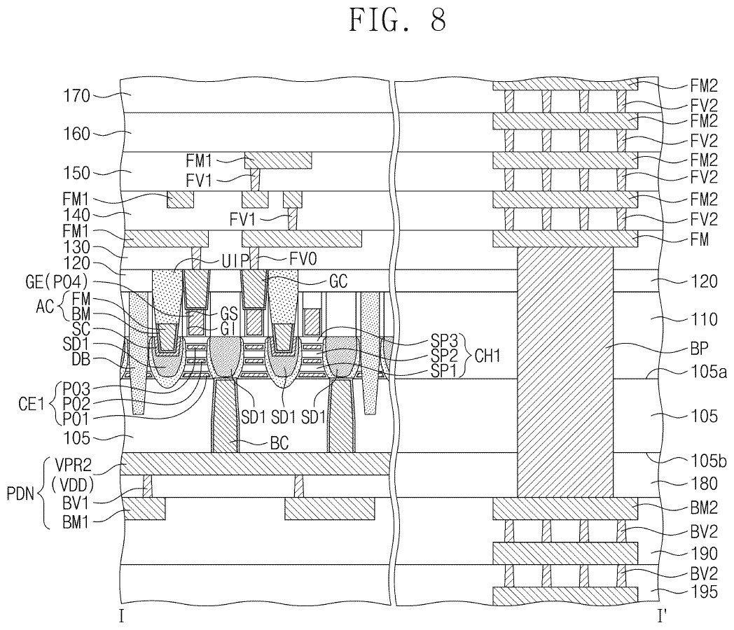

FIG. 7 illustrates a plan view partially showing a semiconductor device according to some example embodiments of the present inventive concepts. FIG. 8 illustrates a cross-sectional view taken along line I-I′ of FIG. 7, showing a semiconductor device according to some example embodiments of the present inventive concepts.

Referring to FIGS. 6 to 8, the first substrate 105 may be provided thereon with logic transistors included in the logic block IP. The first substrate 105 may include a silicon-based dielectric layer. For example, the first substrate 105 may be a dielectric substrate. For example, the first substrate 105 may include a silicon oxide layer, a silicon nitride layer, or a silicon oxynitride layer. However, example embodiments are not limited thereto.

The first substrate 105 may have a first PMOSFET region PR1, a second PMOSFET region PR2, a first NMOSFET region NR1, and a second NMOSFET region NR2. Each of the first PMOSFET region PR1, the second PMOSFET region PR2, the first NMOSFET region NR1, and the second NMOSFET region NR2 may extend in a second direction D2.

The first substrate 105 may be provided on its upper portion with first and second dielectric patterns (or active patterns) that extend along the second direction D2. The first and second dielectric patterns may be vertically protruding portions of the first substrate 105. The first dielectric pattern may be provided on each of the first and second PMOSFET regions PR1 and PR2. The second dielectric pattern may be provided on each of the first and second NMOSFET regions NR1 and NR2.

First channel patterns CH1 may be correspondingly provided on the first and second PMOSFET regions PR1 and PR2, and second channel patterns may be correspondingly provided on the first and second NMOSFET regions NR1 and NR2.

Each of the first channel pattern CH1 and the second channel pattern may include a first semiconductor pattern SP1, a second semiconductor pattern SP2, and a third semiconductor pattern SP3 that are sequentially stacked. The first, second, and third semiconductor patterns SP1, SP2, and SP3 may be spaced apart from each other in a vertical direction (or a third direction D3).

Each of the first, second, and third semiconductor patterns SP1, SP2, and SP3 may include silicon (Si), germanium (Ge), or silicon-germanium (SiGe). However, example embodiments are not limited thereto. For example, each of the first, second, and third semiconductor patterns SP1, SP2, and SP3 may include crystalline silicon. Each of the first, second, and third semiconductor patterns SP1, SP2, and SP3 may be a nano-sheet.

First source/drain patterns SD1 may be provided on opposite sides of the first channel pattern CH1. The first source/drain patterns SD1 may be impurity regions having a first conductivity type (e.g., p-type). The first channel pattern CH1 may be interposed between a pair of first source/drain patterns SD1. For example, the pair of first source/drain patterns SD1 may be connected through the stacked first, second, and third semiconductor patterns SP1, SP2, and SP3.

Second source/drain patterns (not shown) may be provided on opposite sides of each of the second channel patterns provided on the first and second NMOSFET regions NR1 and NR2. The second source/drain patterns may be impurity regions having a second conductivity type (e.g., n-type). The second channel pattern (not shown) may be interposed between a pair of second source/drain patterns. For example. The pair of second source/drain patterns may be connected through the stacked first, second, and third semiconductor patterns SP1, SP2, and SP3.

The first source/drain patterns SD1 may be epitaxial patterns formed by a selective epitaxial growth (SEG) process. For example, a top surface of each of the first source/drain patterns SD1 may be located at substantially the same level as that of a top surface of the third semiconductor pattern SP3. For another example, the top surface of each of the first source/drain patterns SD1 may be higher than the top surface of the third semiconductor pattern SP3. Likewise, the second source/drain patterns may be epitaxial patterns.

The first source/drain pattern SD1 may further include an n-type dopant (e.g., phosphorus, arsenic, or antimony). The first source/drain patterns SD1 may include a semiconductor element (e.g., SiGe) whose lattice constant is greater than that of a semiconductor element of the first channel pattern CH1. Therefore, a pair of first source/drain patterns SD1 may provide a compressive stress to the first channel pattern CH1 therebetween. The second source/drain patterns provided on the first and second NMOSFET regions NR1 and NR2 may include the same semiconductor element (e.g., Si) as that of the second channel pattern.

Each of the second source/drain patterns may include silicon (Si). The second source/drain pattern may further include an n-type dopant (e.g., phosphorus, arsenic, or antimony).

Gate electrodes GE may be provided to extend in the first direction D1, while running across the first channel patterns CH1 and the second channel patterns CH2. The gate electrodes GE may be arranged at a first pitch in the second direction D2.

The gate electrode GE may include a first inner electrode PO1 interposed between the first substrate 105 and the first semiconductor pattern SP1, a second inner electrode PO2 interposed between the first semiconductor pattern SP1 and the second semiconductor pattern SP2, a third inner electrode PO3 interposed between the second semiconductor pattern SP2 and the third semiconductor pattern SP3, and an outer electrode PO4 on the third semiconductor pattern SP3.

The gate electrode GE may be provided on a top surface, a bottom surface, and opposite sidewalls of each of the first, second, and third semiconductor patterns SP1, SP2, and SP3. For example, a transistor according to some example embodiments may be a three-dimensional field effect transistor (e.g., MBCFET or GAAFET) in which the gate electrode GE three-dimensionally surrounds a channel.

Gate cutting patterns CT may be disposed to correspondingly overlap the gate electrodes GE. The gate cutting patterns CT may include a dielectric material, such as a silicon oxide layer, a silicon nitride layer, or a combination thereof.

The gate electrode GE may be divided in the first direction D1 by the gate cutting pattern CT. For example, the gate cutting patterns CT may divide the gate electrode GE, which extends in the first direction D1, into a plurality of gate electrodes GE.

A pair of gate spacers GS may be disposed on opposite sidewalls of the outer electrode PO4 of the gate electrode GE. The gate spacers GS may extend in the first direction D1 along the gate electrode GE. The gate spacers GS may have top surfaces higher than that of the gate electrode GE. The top surfaces of the gate spacers GS may be coplanar (and/or substantially coplanar) with that of a first interlayer dielectric layer 110 which will be discussed below. The gate spacers GS may include at least one selected from SiCN, SiCON, and SiN. Alternatively, the gate spacers GS may each include a multiple layer formed of at least two selected from SiCN, SiCON, and SiN. However, example embodiments are not limited thereto.

A gate capping pattern GP may be provided on the gate electrode GE. The gate capping pattern GP may extend in the first direction D1 along the gate electrode GE. The gate capping pattern GP may include a material having an etch selectivity with respect to first and second interlayer dielectric layers 110 and 120 which will be discussed below. For example, the gate capping pattern GP may include at least one selected from SiON, SiCN, SiCON, and SiN. However, example embodiments are not limited thereto.

A gate dielectric layer GI may be interposed between the gate electrode GE and the first channel pattern CH1 and between the gate electrode GE and the second channel pattern (not shown). The gate dielectric layer GI may cover a top surface, a bottom surface, and opposite sidewalls of each of the first, second, and third semiconductor patterns SP1, SP2, and SP3.

The gate dielectric layer GI may include one or more of a silicon oxide layer, a silicon oxynitride layer, and a high-k dielectric layer. The high-k dielectric layer may include a high-k dielectric material whose dielectric constant is greater than that of a silicon oxide layer. For example, the high-k dielectric material may include at least one selected from hafnium oxide, hafnium silicon oxide, hafnium zirconium oxide, hafnium tantalum oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, and lead zinc niobate. However, example embodiments are not limited thereto.

The gate electrode GE may include a first metal pattern and a second metal pattern on the first metal pattern. The first metal pattern may be provided on the gate dielectric layer GI and may be adjacent to the first, second, and third semiconductor patterns SP1, SP2, and SP3. The first metal pattern may include a work-function metal that controls a threshold voltage of a transistor. A thickness and composition of the first metal pattern may be adjusted to achieve a desired threshold voltage of a transistor. For example, the first, second, and third inner electrodes PO1, PO2, and PO3 of the gate electrode GE may be formed of the first metal pattern or the work-function metal.

The first metal pattern may include a metal nitride layer. For example, the first metal pattern may include nitrogen (N) and at least one metal selected from titanium (Ti), tantalum (Ta), aluminum (Al), tungsten (W), and molybdenum (Mo). In addition, the first metal pattern may further include carbon (C). However, example embodiments are not limited thereto. The first metal pattern may include a plurality of stacked work-function metal layers.

The second metal pattern may include metal whose resistance is less than that of the first metal pattern. For example, the second metal pattern may include at least one metal selected from tungsten (W), aluminum (Al), titanium (Ti), and tantalum (Ta). However, example embodiments are not limited thereto. For example, the outer electrode PO4 of the gate electrode GE may include a first metal pattern and a second metal pattern on the first metal pattern.

A first interlayer dielectric layer 110 may be provided on the first substrate 105. The first interlayer dielectric layer 110 may cover the gate spacers GS, the first source/drain patterns SD1, and the second source/drain patterns. The first interlayer dielectric layer 110 may have a top surface substantially coplanar with that of the gate capping pattern GP and that of the gate spacer GS. The first interlayer dielectric layer 110 may be provided thereon with a second interlayer dielectric layer 120 that covers the gate capping pattern GP. The second interlayer dielectric layer 120 may be provided thereon with third, fourth, fifth, sixth, and seventh interlayer dielectric layers 130, 140, 150, 160, and 170. The first to seventh interlayer dielectric layers 110 to 170 may be provided therein with upper lines FM1 and upper vias FV0 and FV1 that are connected to the logic block IP. The stack number of interlayer dielectric layers and the stack number of the upper lines FM1 connected to the logic block IP may be variously changed. For example, the first to seventh interlayer dielectric layers 110 to 170 may include a silicon oxide layer. The first to seventh interlayer dielectric layers 110 to 170 may be called the front interlayer dielectric layer FILD discussed in FIG. 4.

A pair of separation structures DB may stand opposite to each other in the second direction D2 and extend in the first direction D1 parallel to the gate electrodes GE. A pitch between the separation structure DB and its adjacent gate electrode GE may be the same as the first pitch.

The separation structure DB may penetrate the gate capping pattern GP and the gate electrode GE, thereby extending into the first substrate 105. The separation structure DB may penetrate an upper portion of the first substrate 105.

Active contacts AC may be provided to penetrate the first and second interlayer dielectric layers 110 and 120 to correspondingly come into electrical connection with the first source/drain patterns SD1 and the second source/drain patterns. Each of the active contacts AC may be provided adjacent to one side of the gate electrode GE. When viewed in plan, the active contact AC may have a bar shape that extends in the first direction D1.

The active contact AC may be a self-aligned contact. For example, the gate capping pattern GP and the gate spacer GS may be used to form the active contact AC in a self-alignment manner. The active contact AC may cover, for example, at least a portion of a sidewall of the gate spacer GS. Although not shown, the active contact AC may cover a portion of the top surface of the gate capping pattern GP.

A metal-semiconductor compound layer SC, or a silicide layer, may be interposed between the active contact AC and the first source/drain pattern SD1 and between the active contact AC and the second source/drain pattern. The active contact AC may be electrically connected through the metal-semiconductor compound layer SC to one of the first source/drain pattern SD1 and the second source/drain pattern. For example, the metal-semiconductor compound layer SC may include at least one selected from titanium silicide, tantalum silicide, tungsten silicide, nickel silicide, and cobalt silicide. However, example embodiments are not limited thereto.

Gate contacts GC may be provided to penetrate the second interlayer dielectric layer 120 and the gate capping pattern GP to come into electrical connection with the gate electrodes GE. When viewed in plan, two gate contacts GC may be disposed to overlap the first PMOSFET region PR1. The gate contact GC may be freely located with no limitation of position on the gate electrode GE.

An upper dielectric pattern UIP may fill an upper portion of the active contact AC, which upper portion is adjacent to the gate contact GC. The upper dielectric pattern UIP may have a bottom surface lower than that of the gate contact GC. For example, the upper dielectric pattern UIP may cause the active contact AC adjacent to the gate contact GC to have a top surface lower than the bottom surface of the gate contact GC. Therefore, it may be possible to reduce and/or prevent a short circuit resulting from contact between the gate contact GC and its adjacent active contact AC. For example, the upper dielectric pattern UIP may include a silicon-based dielectric material (e.g., a silicon oxide layer, a silicon nitride layer, or a silicon oxynitride layer).

The active contact AC may include a conductive pattern FM and a barrier metal pattern BM that surrounds the conductive pattern FM. For example, the conductive pattern FM may include at least one metal selected from aluminum, copper, tungsten, molybdenum, and cobalt. However, example embodiments are not limited thereto. The barrier metal pattern BM may cover sidewalls and a bottom surface of the conductive pattern FM. The barrier metal pattern BM may include a metal layer and a metal nitride layer. The metal layer may include at least one selected from titanium, tantalum, tungsten, nickel, cobalt, and platinum. However, example embodiments are not limited thereto. The metal nitride layer may include at least one selected from a titanium nitride (TiN) layer, a tantalum nitride (TaN) layer, a tungsten nitride (WN) layer, a nickel nitride (NiN) layer, a cobalt nitride (CON) layer, and a platinum nitride (PtN) layer. However, example embodiments are not limited thereto. Likewise, the gate contact GC may include a conductive pattern and a barrier metal pattern that surrounds the conductive pattern. The conductive pattern and the barrier metal pattern may include their materials substantially the same as those of the conductive pattern FM and the barrier metal pattern BM included in the active contact AC.

A power delivery network PDN may be provided on the second surface 105b of the first substrate 105. The power delivery network PDN may include first, second, and third lower power lines VPR1, VPR2, and VPR3 and a plurality of backside lines BM1 electrically connected to the first, second, and third lower power lines VPR1, VPR2, and VPR3.

The first, second, and third lower power lines VPR1, VPR2, and VPR3 may parallel extend in the second direction D2. The first lower power line VPR1 may vertically overlap the first NMOSFET region NR1. The second lower power line VPR2 may vertically overlap the first PMOSFET region PR1 and the second PMOSFET region PR2. The third lower power line VPR3 may vertically overlap the second NMOSFET region NR2.

The first, second, and third lower power lines VPR1, VPR2, and VPR3 may include at least one selected from copper, molybdenum, tungsten, and ruthenium. Each of the first, second, and third lower power lines VPR1, VPR2, and VPR3 may be in contact with the second surface 105b of the first substrate 105.

The first and third lower power lines VPR1 and VPR3 may be paths for providing a source voltage, for example, a ground voltage VSS. The second lower power line VPR2 may be a path for providing a drain voltage, for example, a power voltage VDD.

A backside contact BC may be provided to penetrate the first substrate 105 to vertically extend from the second lower power line VPR2 to the first source/drain pattern SD1.

The backside contact BC may have a conductive pillar shape that vertically and electrically connects the second lower power line VPR2 to the first source/drain pattern SD1. The power voltage VDD may be applied through the backside contact BC to the first source/drain pattern SD1. The backside contact BC may include, for example, at least one metal selected from tungsten, molybdenum, ruthenium, cobalt, aluminum, or copper. However, example embodiments are not limited thereto.

First, second, and third backside dielectric layers 180, 190, and 195 may be sequentially stacked on the second surface 105b of the first substrate 105, and backside lines BM1 may be provided in the first, second, and third backside dielectric layers 180, 190, and 195. The first, second, and third backside dielectric layers 180, 190, and 195 may include, for example, silicon oxide, and may be called a backside interlayer dielectric layer BILD.

According to some example embodiments, the through conductive pattern BP may be horizontally spaced apart from the logic block IP to penetrate in the third direction D3 through the first substrate 105. A vertical length of the through conductive pattern BP may be greater than that of the backside contact BC. For example, the through conductive pattern BP may penetrate the first and second interlayer dielectric layers 110 and 120 and the first backside dielectric layer 180.

The through conductive pattern BP may have a circular pillar, a tetragonal pillar, or a polygonal pillar. When viewed in one direction (e.g., the second direction D2), a width of the through conductive pattern BP may be greater than that of the backside contact BC. The through conductive pattern BP may include, for example, at least one metal selected from copper, aluminum, tungsten, molybdenum, and cobalt. However, example embodiments are not limited thereto. In addition, the through conductive pattern BP may further include a metal nitride layer (not shown) that covers a sidewall thereof. The metal nitride layer may include, for example, at least one selected from a titanium nitride (TiN) layer, a tantalum nitride (TaN) layer, a tungsten nitride (WN) layer, a nickel nitride (NiN) layer, a cobalt nitride (CON) layer, and a platinum nitride (PIN) layer. However, example embodiments are not limited thereto.

Upper conductive patterns FM2 and upper conductive vias FV2 may be alternately stacked on a top surface of the through conductive pattern BP. Lower conductive patterns BM2 and lower conductive vias BV2 may be sequentially stacked on a bottom surface of the through conductive pattern BP.

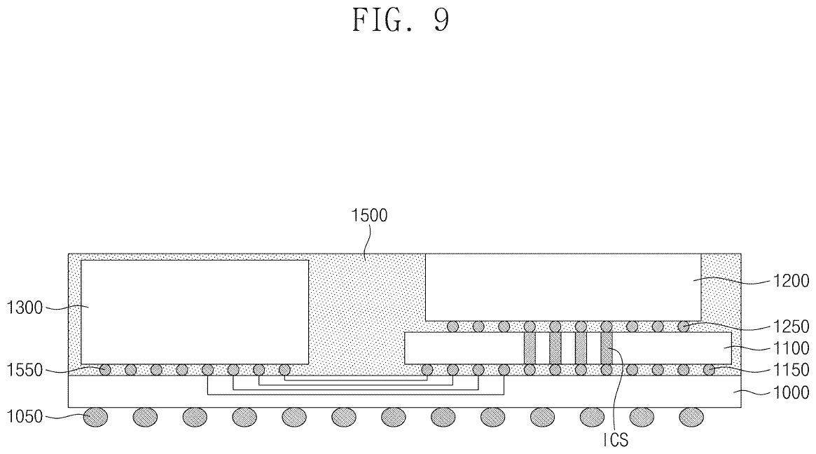

FIG. 9 illustrates a cross-sectional view showing a semiconductor package including a semiconductor device according to some example embodiments of the present inventive concepts.

Referring to FIG. 9, a semiconductor package may include a first redistribution substrate 1000, a first semiconductor device 1100, a second semiconductor device 1200, and a third semiconductor device 1300. The first semiconductor device 1100 and the third semiconductor device 1300 may be mounted on the first redistribution substrate 1000, and the second semiconductor device 1200 may be mounted on the first semiconductor device 1100.

In some example embodiments, the first redistribution substrate 1000, the first semiconductor device 1100, and the second semiconductor device 1200 may include their components substantially the same as those of the example embodiments discussed above with reference to FIG. 1. For example, the first semiconductor device 1100 may include the connection structures ICS discussed above, and the second semiconductor device 1200 may be electrically connected through the connection structures ICS to the first redistribution substrate 1000.

First connection terminals 1050 may be attached to a lower portion of the first redistribution substrate 1000, and second connection terminals 1150 may be attached to an upper portion of the first redistribution substrate 1000. In addition, third connection terminals 1250 may be connected between the first semiconductor device 1100 and the second semiconductor device 1200. The first, second, and third connection terminals 1050, 1150, and 1250 may be at least one selected from solder balls, conductive bumps, and conductive pillars. The first, second, and third connection terminals 1050, 1150, and 1250 may include, for example, at least one selected from copper, tin, and lead. However, example embodiments are not limited thereto.

The semiconductor package may use the first connection terminals 1050 to transceive signals with an external other package or other semiconductor devices. For example, a power signal (or a ground signal) for driving the first and second semiconductor devices 1100 and 1200 may be received through at least one among the first connection terminals 1050 of the first redistribution substrate 1000.

The first redistribution substrate 1000 may connect the first semiconductor device 1100 and the third semiconductor device 1300 to each other. The first redistribution substrate 1000 may connect the first semiconductor device 1100 and the third semiconductor device 1300 to each other, and may provide physical paths formed with conductive materials. Therefore, the first semiconductor device 1100 and the third semiconductor device 1300 may be mounted on the first redistribution substrate 1000 and may transceive signals with each other.

The semiconductor device 1200 may use the first semiconductor device 1100 to execute applications supported by the semiconductor package. For example, the second semiconductor device 1200 may include at least one processor selected from a central processing unit (CPU), an application processor (AP), a graphic processing unit (GPU), a neutral processing unit (NPU), a tensor processing unit (TPU), a vision processing unit (VPU), an image signal processor (ISP), and a digital signal processor (DSP), thereby carrying out specialized calculations.

On the first redistribution substrate 1000, the third semiconductor device 1300 may be disposed horizontally spaced apart from the first semiconductor device 1100. The third semiconductor device 1300 may include a memory chip. For example, the memory chip may include one or more of DRAM, SRAM, MRAM, and NAND Flash memory. However, example embodiments are not limited thereto.

Fourth connection terminals 1550 may be disposed between the third semiconductor device 1300 and the first redistribution substrate 1000. The third semiconductor device 1300 may be electrically connected through the fourth connection terminals 1550 to the first redistribution substrate 1000. The fourth connection terminals 1550 may connect chip pads of the third semiconductor device 1300 to upper bonding pads of the first redistribution substrate 1000. In addition, the third semiconductor device 1300 may be electrically connected to the first semiconductor device 1100 and the second semiconductor device 1200 through redistribution lines in the first redistribution substrate 1000.

The semiconductor package may further include a molding layer 1500 that covers lateral surfaces of the first, second, and third semiconductor devices 1100, 1200, and 1300 and a top surface of the first redistribution substrate 1000. A lateral surface of the molding layer 1500 may be substantially coplanar with that of the first redistribution substrate 1000. The molding layer 1500 may include, for example, an epoxy molding compound (EMC). However, example embodiments are not limited thereto.

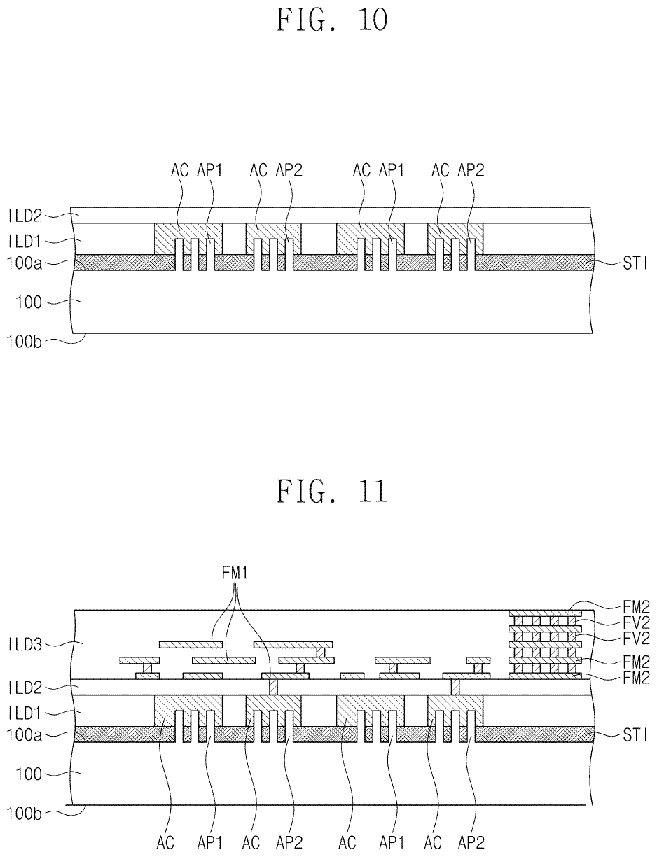

FIGS. 10 to 12E illustrate cross-sectional views showing a method of fabricating a semiconductor device according to some example embodiments of the present inventive concepts.

Referring to FIG. 10, a first semiconductor substrate 100 may be provided. The first semiconductor substrate 100 may be, for example, a silicon substrate. The first semiconductor substrate 100 may have a first surface 100a and a second surface 100b opposite to the first surface 100a.

First and second active patterns AP1 and AP2 may be formed on the first surface 100a of the first semiconductor substrate 100. The first and second active patterns AP1 and AP2 may have a linear shape that extends in a first direction D1. The first and second active patterns AP1 and AP2 may be formed by patterning the first semiconductor substrate 100 to form trenches. The first and second active patterns AP1 and AP2 may be portions of the first semiconductor substrate 100, and may be defined by the trenches formed in the first semiconductor substrate 100.

A device isolation layer STI may be formed between the first and second active patterns AP1 and AP2. A top surface of the device isolation layer STI may be located lower than top surfaces of the first and second active patterns AP1 and AP2 to expose upper portions of the first and second active patterns AP1 and AP2.

A gate electrode (see GE of FIG. 8) and active contacts AC may be formed. The active contacts AC may be in contact with the first and second active patterns AP1 and AP2. Each of the active contacts AC may include a barrier metal layer and a metal layer.

A first interlayer dielectric layer ILD1 may be formed on the first semiconductor substrate 100. The first interlayer dielectric layer ILD1 may cover gate spacers (see GS of FIG. 9), first source/drain patterns (see SD1 of FIG. 9), and second source/drain patterns. A second interlayer dielectric layer ILD2 may be stacked on the first interlayer dielectric layer ILD1.

Referring to FIG. 11, upper lines FM1 may be stacked on the second interlayer dielectric layer ILD2. The upper lines FM1 may be formed in a third interlayer dielectric layer ILD3 including a plurality of dielectric layers. The upper lines FM1 vertically stacked may be electrically connected through contact plugs, and may be coupled to a logic block (or gate electrodes and active contacts). Upper conductive patterns FM2 and upper conductive vias FV2 may be formed concurrently with the upper lines FM1 connected to the logic block. An uppermost upper conductive pattern FM2 may be coplanar (and/or substantially coplanar) with the third interlayer dielectric layer ILD3. The first, second, and third interlayer dielectric layers ILD1, ILD2, and ILD3 may include, for example, silicon oxide, and may be called a front interlayer dielectric layer FILD of FIG. 4.

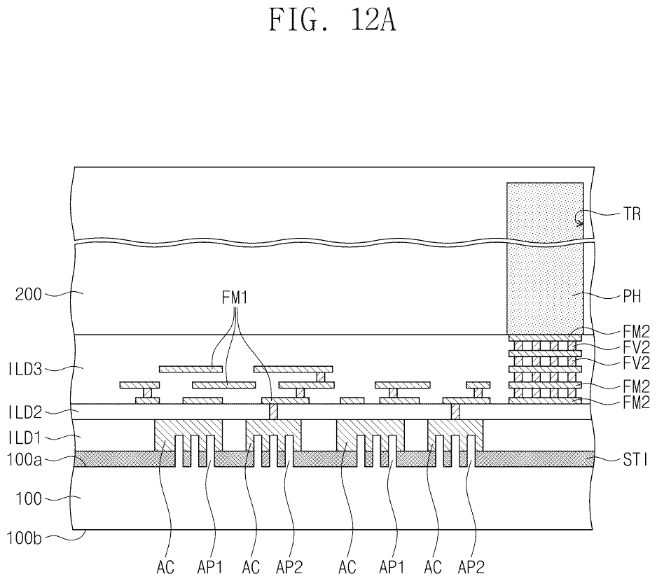

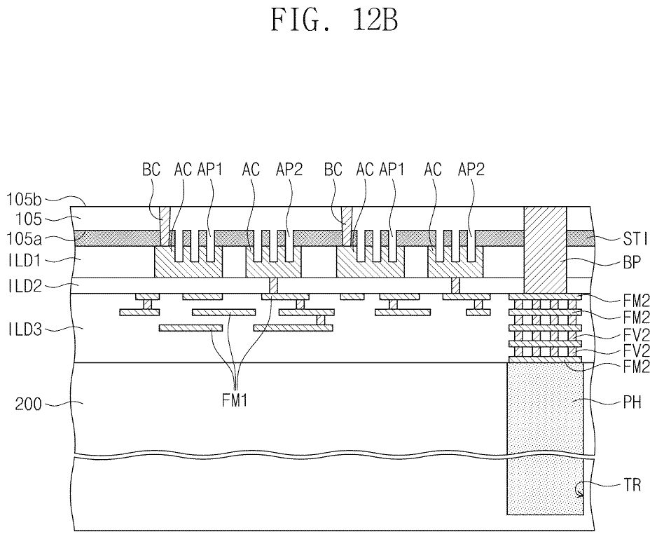

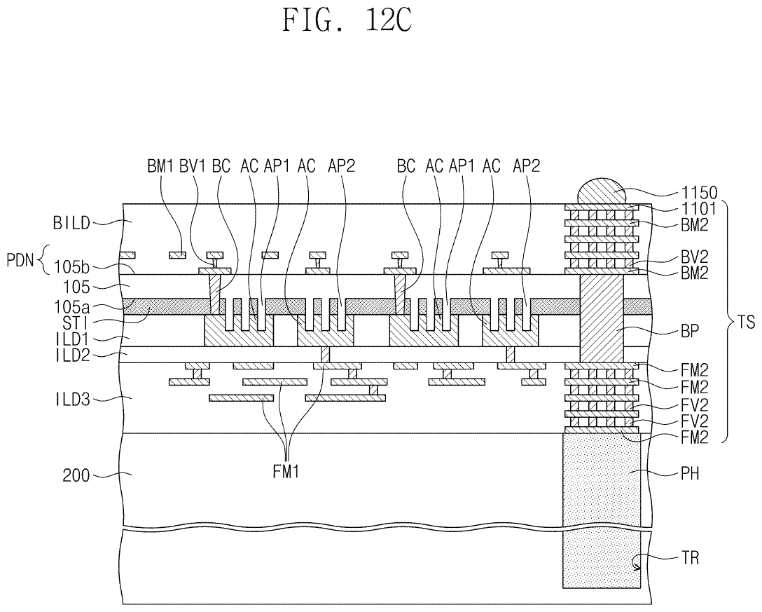

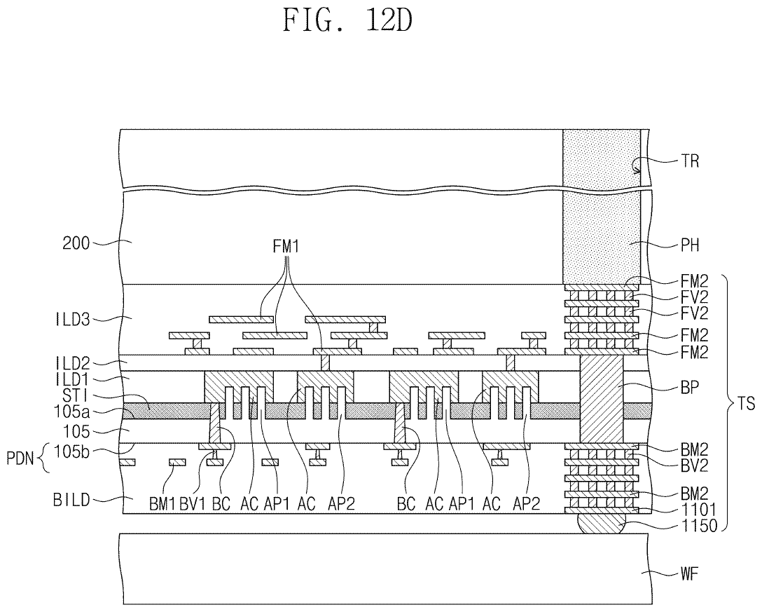

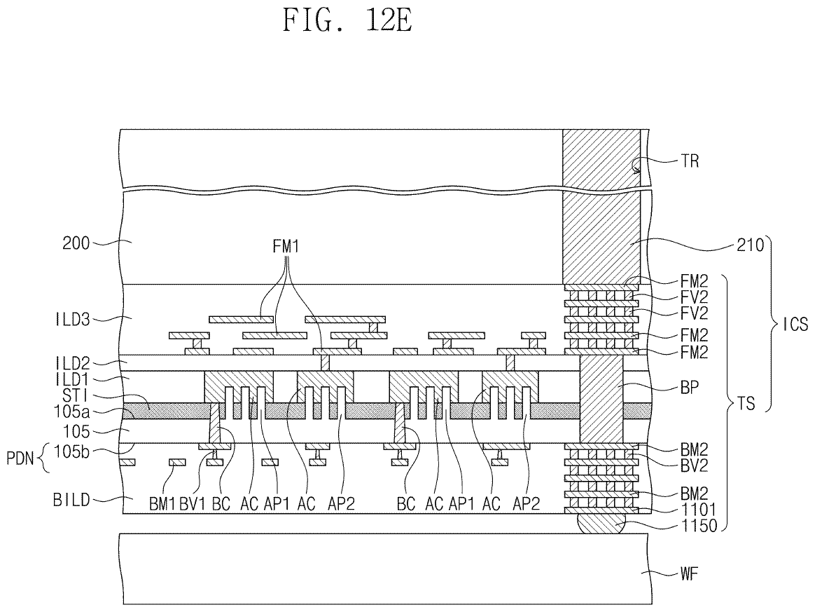

Referring to FIG. 12A, a second substrate 200 may be prepared. The second substrate 200 may be patterned on its one surface to form a trench TR. A sacrificial pattern PH may fill the trench TR of the second substrate 200. The second substrate 200 may be disposed on the third interlayer dielectric layer ILD3. The second substrate 200 and the third interlayer dielectric layer ILD3 may be adhered to allow the sacrificial pattern PH filling the trench TR to contact the uppermost one of the upper conductive patterns FM2. An adhesion layer (not shown) may further be disposed between the second substrate 200 and the third interlayer dielectric layer ILD3. The second substrate 200 may be, for example, a silicon substrate, and may further include silicon carbide. However, example embodiments are not limited thereto.

Referring to FIGS. 12A and 12B, a thinning process may be performed to reduce a thickness of the first semiconductor substrate 100. The thinning process may include grinding or polishing the second surface 100b of the first semiconductor substrate 100 and/or anisotropically or isotropically etch the second surface 100b of the first semiconductor substrate 100.

The first semiconductor substrate 100 may be turned upside down, the grinding or polishing process may remove a portion of the first semiconductor substrate 100, and then the anisotropic or isotropic etching process may be performed to surface defects remaining on the first semiconductor substrate 100.

A process may be executed to replace the first semiconductor substrate 100 with a first substrate 105 formed of a dielectric material. Likewise the first semiconductor substrate 100, the first substrate 105 may include the first and second active patterns AP1 and AP2. In addition, the first substrate 105 may have a first surface 105a in contact with the device isolation layer STI and a second surface 105b opposite to the first surface 105a.

The second surface 105b of the first substrate 105 may be patterned to form through holes that expose one or more of the active contacts AC and the source/drain patterns. A vertical length of the through holes may be equal to or substantially equal to or less than about 1 μm. The through holes may be filled with a metallic material, and then the metallic material may be planarized such that the second surface 105b of the first substrate 105 may be exposed to form backside contacts BC.

After the formation of the backside contacts BC, a through conductive pattern BP may be formed to penetrate the first substrate 105. The through conductive pattern BP may be formed by partially patterning the second surface 105b of the first substrate 105 and the first and second interlayer dielectric layers ILD1 and ILD2 to form through holes that expose the upper conductive pattern FM2, filling the through holes with a metallic material, and then planarizing the metallic material to expose the second surface 105b of the first substrate 105.

Referring to FIG. 12C, after the formation of the through conductive pattern BP, a power delivery network PDN may be formed on the second surface 105b of the first substrate 105. The formation of the power delivery network PDN may include forming a plurality of power lines or backside lines BM1 across backside interlayer dielectric layers BILD therebetween. In addition, during the formation of the backside lines BM1, lower conductive patterns BM2 and lower conductive vias BV2 may be simultaneously formed on the through conductive pattern BP. An uppermost one of the lower conductive patterns BM2 may be called a lower chip pad 1101.

The lower chip pad 1101 may be electrically connected to the through conductive pattern BP through the lower conductive patterns BM2 and the lower conductive vias BV2. As even the lower chip pad 1101 is formed, a first through structure TS may be formed which includes the through conductive pattern BP, the upper conductive patterns FM2, and the lower conductive patterns BM2.

A second connection terminal 1150 may be attached to the lower chip pad 1101. The lower chip pad 1101 may include at least one selected from copper, nickel, zinc, gold, silver, platinum, palladium, chromium, titanium, and an alloy thereof. The second connection terminal 1150 may include at least one selected from tin, silver, lead, nickel, copper, and an alloy thereof. However, example embodiments are not limited thereto.

Referring to FIG. 12D, a sub-substrate WF may be disposed which is connected to the second connection terminal 1150. The sub-substrate WF may be the first redistribution substrate 1000 discussed above in FIG. 1, but the present inventive concepts are not limited thereto. The sub-substrate WF may be attached to the second connection terminal 1150, and then the second substrate 200 may be turned upside down.

Referring to FIG. 12E, the sacrificial pattern PH in the trench TR may be selectively removed. A second through structure 210 may be formed in the trench TR from which the sacrificial pattern PH is removed. The formation of the second through structure 210 may be formed by filling the trench TR with a metallic material, and then planarizing the metallic material to expose a top surface of the second substrate 200. The second through structure 210 penetrating the second substrate 200 may be formed to achieve a connection structure ICS.

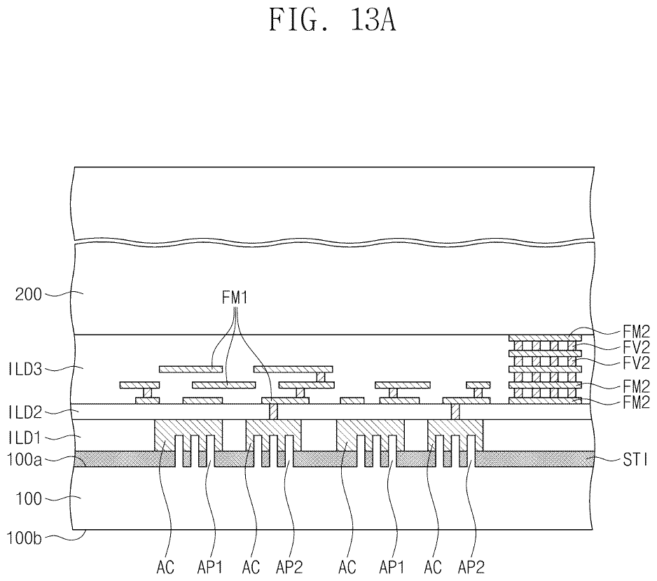

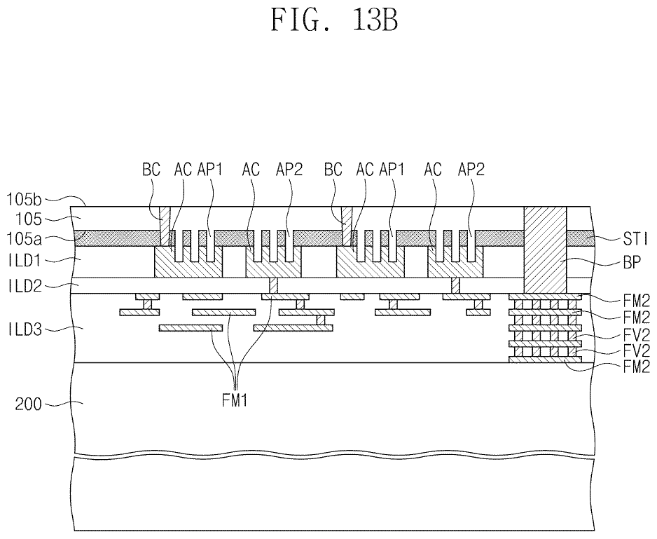

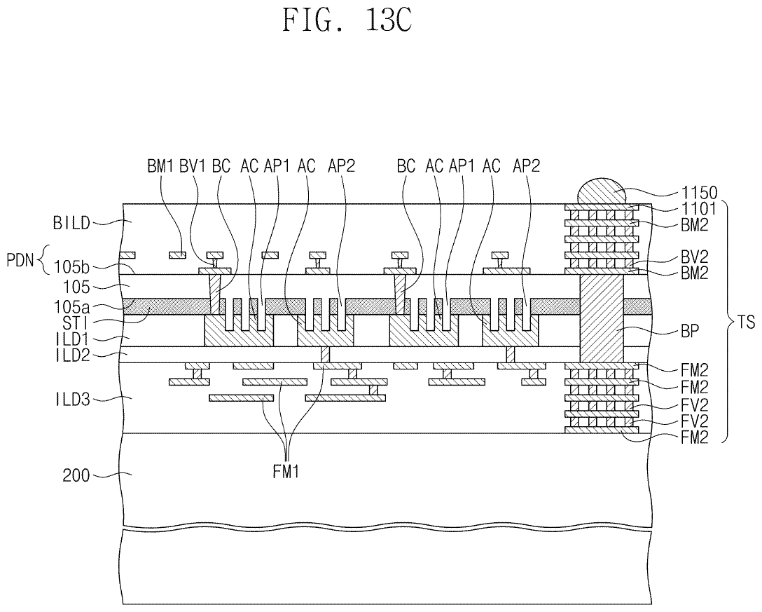

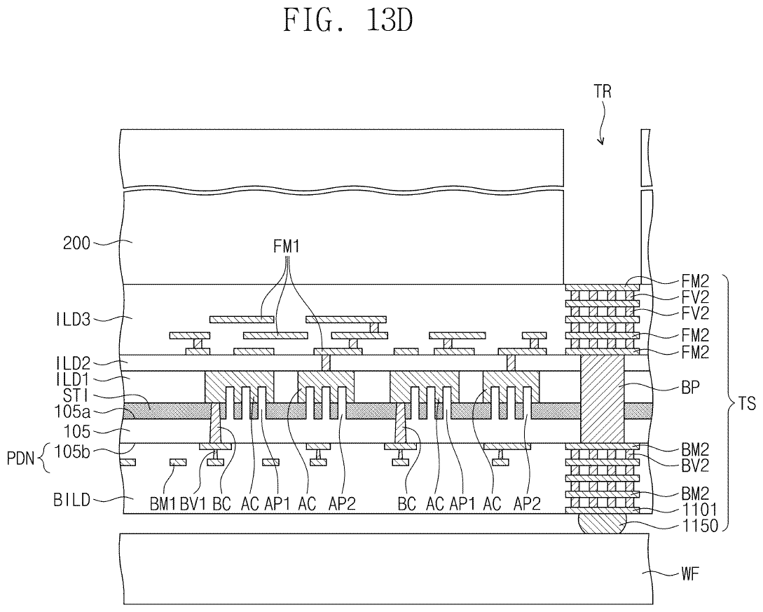

FIGS. 13A to 13D illustrate cross-sectional views showing a method of fabricating a semiconductor device according to some example embodiments of the present inventive concepts, depicting a different fabrication method from the fabrication method of FIGS. 12A to 12D. The method of fabricating a semiconductor device depicted in FIGS. 13A to 13D may be performed followed by the method of fabricating a semiconductor device discussed with reference to FIGS. 10 and 11. For brevity of explanation, a detailed description of technical features the same as those of the semiconductor device discussed above may be omitted, and a difference thereof will be described.

Referring to FIG. 13A, a second substrate 200 may be disposed on the third interlayer dielectric layer ILD3. An adhesion layer (not shown) may further be disposed between the second substrate 200 and the third interlayer dielectric layer ILD3.

Referring to FIG. 13B, a thinning process may be performed to reduce a thickness of the first semiconductor substrate 100.

The first semiconductor substrate 100 may be turned upside down, and a grinding or polishing process may remove a portion of the first semiconductor substrate 100. A process may be executed to replace the first semiconductor substrate 100 with a first substrate 105 formed of a dielectric material.

The second surface 105b of the first substrate 105 may be patterned to form through holes that expose one or more of the active contacts AC and the source/drain patterns. The through holes may be filled with a metallic material, and then the metallic material may be planarized such that the second surface 105b of the first substrate 105 may be exposed to form backside contacts BC. After the formation of the backside contacts BC, a through conductive pattern BP may be formed to penetrate the first substrate 105.

Referring to FIG. 13C, after the formation of the through conductive pattern BP, a power delivery network PDN may be formed on the second surface 105b of the first substrate 105. The power delivery network PDN may include a plurality of power lines or backside lines BM1 across backside interlayer dielectric layers BILD therebetween. In addition, during the formation of the backside lines BM1, lower conductive patterns BM2 and lower conductive vias BV2 may be simultaneously formed on the through conductive pattern BP. An uppermost one of the lower conductive patterns BM2 may be called a lower chip pad 1101. A second connection terminal 1150 may be attached to the lower chip pad 1101.

Referring to FIGS. 13D and 12E, a sub-substrate WF may be disposed which is connected to the second connection terminal 1150. The sub-substrate WF may be the first redistribution substrate 1000 discussed above in FIG. 1, but the present inventive concepts are not limited thereto. The sub-substrate WF may be attached to the second connection terminal 1150, and then the second substrate 200 may be turned upside down.

The second substrate 200 may be patterned to form a trench TR that penetrates the second substrate 200. A second through structure 210 may be formed by filling the trench TR with a metallic material, and then planarizing the metallic material to expose a top surface of the second substrate 200.

According to some example embodiments of the present inventive concepts, a connection structure may be provided to electrically connect top and bottom ends of a semiconductor chip. The connection structure may include a first through structure that penetrates a first substrate on which logic blocks are formed and a second through structure that penetrates a second substrate on the first substrate. The connection structure may serve as an electrical path between vertically stacked semiconductor chips. In addition, the first through structure may include upper and lower lines and a through conductive via that penetrates the first substrate, and the upper and lower lines may be appropriately disposed to bypass the logic block. Therefore, it may be possible to form a large region for the logic blocks provided in a semiconductor device and to improve the degree of design freedom and/or integration of the semiconductor device.

Additionally, heat generated due to operation of a semiconductor chip may be transferred to the second substrate with excellent thermal conductivity, and may be outwardly discharged through sidewalls of the second substrate. Accordingly, the semiconductor chip may improve in thermal radiation performance and/or may be at least partially reduced and/or prevented from degradation of the semiconductor chip.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

Although the present invention has been described in connection with some example embodiments of the present inventive concepts illustrated in the accompanying drawings, it will be understood to those skilled in the art that various changes and modifications may be made without departing from the technical spirit and essential feature of the present inventive concepts. It will be apparent to those skilled in the art that various substitution, modifications, and changes may be thereto without departing from the scope and spirit of the inventive concepts.

What is claimed is:

1. A semiconductor device, comprising:
a first substrate having a first surface and a second surface facing each other;
a logic block on the first surface of the first substrate;
a power delivery network on the second surface of the first substrate, and the power delivery network including a plurality of backside lines connected to the logic block;
a second substrate on the logic block opposite to the first surface of the first substrate;
a first through structure penetrating the first substrate; and
a second through structure penetrating the second substrate, and the second through structure electrically connected to the first through structure,
wherein the first through structure comprises
a through conductive pattern horizontally spaced apart from the logic block and penetrating the first substrate,
a plurality of upper conductive patterns stacked on a top surface of the through conductive pattern, and
a plurality of lower conductive patterns stacked on a bottom surface of the through conductive pattern.

2. The semiconductor device of claim 1, wherein the upper conductive patterns and the lower conductive patterns vertically overlap the through conductive pattern.

3. The semiconductor device of claim 1, wherein the first through structure comprises:
a plurality of upper conductive vias between the upper conductive patterns, and
a plurality of lower conductive vias between the lower conductive patterns.

4. The semiconductor device of claim 1, further comprising:
a front interlayer dielectric layer on the first surface of the first substrate, the front interlayer dielectric layer covering the upper conductive patterns,
wherein the second through structure penetrates at least a portion of the front interlayer dielectric layer.

5. The semiconductor device of claim 1, wherein the second through structure comprises:
a first conductive via vertically connected to the first through structure, and
a conductive line connected to the first conductive via, and the conductive line extending in a direction parallel to a bottom surface of the second substrate.

6. The semiconductor device of claim 5, further comprising:
a plurality of upper lines on the first surface of the first substrate, and the plurality of upper lines connected to the logic block,
wherein the second through structure further comprises
a second conductive via connected to the conductive line, and the second conductive via horizontally spaced apart from the first conductive via, and
the second conductive via is electrically connected to the upper lines.

7. The semiconductor device of claim 1, further comprising:
a redistribution substrate on the second substrate,
wherein the second through structure is electrically connected to a redistribution pattern of the redistribution substrate.

8. The semiconductor device of claim 1, wherein
the logic block comprises
a plurality of source/drain patterns,
a channel pattern between the source/drain patterns, the channel pattern comprising a plurality of semiconductor patterns stacked and spaced apart from each other,
a gate electrode on the channel pattern,
an active contact on the source/drain patterns, and the active contact connected to one of the source/drain patterns,
a plurality of upper lines connected to the active contact, and
a backside contact below the source/drain patterns, the backside contact connecting another of the source/drain patterns to one of the backside lines.

9. The semiconductor device of claim 1, wherein the second through structure is in contact with an uppermost one of the upper conductive patterns.

10. The semiconductor device of claim 1, further comprising:
a plurality of upper lines on the first surface of the first substrate, and the plurality of upper lines connected to the logic block,
wherein a top surface of a lowermost one of the upper conductive patterns is coplanar with a top surface of at least a portion of the upper lines.

11. The semiconductor device of claim 1, wherein a bottom surface of a lowermost one of the lower conductive patterns is coplanar with a bottom surface of at least a portion of the backside lines.

12. A semiconductor device, comprising:
a first substrate having a first surface and a second surface facing each other;
a logic block on the first surface of the first substrate;
a plurality of upper lines on the first surface of the first substrate and connected to the logic block;
a power delivery network on the second surface of the first substrate, and the power delivery network including a plurality of backside lines connected to the logic block;
a second substrate on the logic block opposite to the first surface of the first substrate; and
a connection structure penetrating the first substrate and the second substrate,
wherein the connection structure comprises
a through conductive pattern penetrating the first substrate, and the through conductive pattern is horizontally spaced apart from the logic block; and
an upper through structure penetrating the second substrate, and the upper through structure electrically connected to the through conductive pattern,
a bottom surface of the upper through structure is at a level lower than a level of a top surface of an uppermost one of the upper lines.

13. The semiconductor device of claim 12, wherein a horizontal width of the through conductive pattern is less than a horizontal width of the upper through structure.

14. The semiconductor device of claim 12, wherein a vertical length of the through conductive pattern is less than a vertical length of the upper through structure.

15. The semiconductor device of claim 12, wherein the upper through structure is vertically spaced apart from the first substrate.

16. The semiconductor device of claim 12, wherein
the logic block comprises
a plurality of source/drain patterns,
a channel pattern between the source/drain patterns, the channel pattern comprising a plurality of semiconductor patterns stacked and spaced apart from each other,
a gate electrode on the channel pattern,
an active contact on the source/drain patterns, and the active contact connected to one of the source/drain patterns,
the plurality of upper lines connected to the active contact, and
a backside contact below the source/drain patterns, and the backside contact connecting another one of the source/drain patterns to one of the backside lines.

17. The semiconductor device of claim 16, wherein a horizontal width of the through conductive pattern is greater than a horizontal width of the backside contact.

18. A semiconductor package, comprising:
a redistribution substrate;
a first semiconductor chip on the redistribution substrate; and
a second semiconductor chip on the first semiconductor chip,
wherein the first semiconductor chip comprises
a logic block on a first surface of a first substrate,
an upper line on the first surface of the first substrate, and the upper line connected to the logic block,
a power delivery network on a second surface of the first substrate, and the power delivery network including a plurality of power lines connected to the logic block,
a second substrate on the logic block opposite to the first surface of the first substrate, and
a connection structure penetrating the first substrate and the second substrate,
the connection structure comprises
a first through structure penetrating the first substrate, and
a second through structure penetrating the second substrate, and the second through structure electrically connected to the first through structure,
the first through structure comprises
a through conductive pattern penetrating the first substrate, and the through conductive pattern is horizontally spaced apart from the logic block,
a plurality of upper conductive patterns on the first surface of the first substrate, and the plurality of upper conductive patterns stacked on a top surface of the through conductive pattern, and
a plurality of lower conductive patterns on the second surface of the first substrate, and the plurality of lower conductive patterns stacked on a bottom surface of the through conductive pattern.

19. The semiconductor package of claim 18, wherein the second through structure vertically overlaps the first through structure.

20. The semiconductor package of claim 18, wherein
the logic block comprises
a plurality of source/drain patterns,
a channel pattern between the source/drain patterns, the channel pattern comprising a plurality of semiconductor patterns stacked and spaced apart from each other,
a gate electrode on the channel pattern,
an active contact on the source/drain patterns, and the active contact connected to one of the source/drain patterns,
a plurality of upper lines connected to the active contact, and a backside contact below the source/drain patterns, and the backside contact connecting another of the source/drain patterns to a backside line.
